(19) United States
(12) Patent Application Publication
(10) Pub. No.: US 2006/0273320 A1
(43) Pub. Date: Dec. 7, 2006

(54) Method of manufacturing semiconductor device

(76) Inventors: Katsuaki Natori, Yokohama-shi (JP); Masayuki Tanaka, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/443,275

(22) Filed: May 31, 2006

(30) Foreign Application Priority Data
Jun. 1, 2005 (JP) 2005-161678

(51) Int. Cl. H01L 29/76

(52) U.S. Cl. 257/66

(57) ABSTRACT

According to an aspect of the invention, there is provided a method of manufacturing a semiconductor device including simultaneously supplying a source gas of an oxide insulating film and H₂ to a semiconductor substrate when the oxide insulating film is formed on the semiconductor substrate by a CVD method.

### CROSS-REFERENCE TO RELATED APPLICATIONS

This application is based upon and claims the benefit of priority from prior Japanese Patent Application No. 2005-161678, filed Jun. 1, 2005, the entire contents of which are incorporated herein by reference.

### BACKGROUND OF THE INVENTION

1. Field of the Invention

The present invention relates to a method of manufacturing a semiconductor device which uses a CVD method as an oxide insulating film forming method.

2. Description of the Related Art

Higher LSI density in recent years has been accompanied by much greater thinning of a capacitor insulating film and a gate insulating film. To prevent the increase in leakage current which accompanies the thinning, countermeasures have been taken to change a structure into a three-dimensional structure, or the increase in leakage current has been suppressed by using a high dielectric constant film to increase physical film thickness.

Especially, in a nonvolatile semiconductor memory device such as a flash memory, regarding an interpoly insulating film formed between a charge storage layer and a control electrode, for example, a three stacked layer film of a silicon oxide film, a silicon nitride film and a silicon oxide film (ONO film) has been used to increase a dielectric constant, and a three-dimensional structure has been applied. However, as a distance is reduced more between cells, interferences of adjacent cells with each other are greatly increased to deteriorate device characteristics, causing a difficulty of an area increase using the three-dimensional structure.

Thus, to realize a next-generation nonvolatile semiconductor memory device, an insulating film having a dielectric constant higher than that of a conventional case must be applied as an interpoly insulating film. Since a capacitor can be increased without increasing the area as a result of applying the high dielectric constant insulating film, the three-dimensional structure is made unnecessary, and a manufacturing process can be simplified. Hence, it is possible to realize a high-yield manufacturing process by achieving higher performance of a device and facilitating a manufacturing method.

An oxide such as Al₂O₃ as the high dielectric constant insulating film has been formed by a chemical vapor deposition (CVD) method such as an atomic layer deposition (ALD) method for reasons of uniformity, coverage, mass productivity, low damage, and the like. In the CVD method, however, an organic metal compound such as trimethyl aluminum (TMA) is used as a source gas, and therefore, carbon (C) impurities are captured into the film to cause problems of increase in leakage current, reduction in dielectric constant, and the like.

Jpn. Pat. Appln. KOKAI Publication No. 2004-104025 discloses a film forming method which introduces an organic metal compound and an oxidizing agent as sources into a CVD device, and forms a metal oxide film on a substrate set in the CVD device.

### BRIEF SUMMARY OF THE INVENTION

According to an aspect of the invention, there is provided a method of manufacturing a semiconductor device, comprising: simultaneously supplying a source gas of an oxide insulating film and H₂ to a semiconductor substrate when the oxide insulating film is formed on the semiconductor substrate by a CVD method.

### BRIEF DESCRIPTION OF THE SEVERAL VIEWS OF THE DRAWING

FIG. 1 is a sectional view showing a manufacturing process of a semiconductor device according to an embodiment of the present invention;

FIG. 2 is a sectional view showing the manufacturing process of the semiconductor device according to the embodiment of the present invention;

FIG. 3 is a sectional view showing the manufacturing process of the semiconductor device according to the embodiment of the present invention;

FIG. 4 is a sectional view showing the manufacturing process of the semiconductor device according to the embodiment of the present invention;

FIG. 5 is a sectional view showing the manufacturing process of the semiconductor device according to the embodiment of the present invention;

FIG. 6 is a sectional view showing the manufacturing process of the semiconductor device according to the embodiment of the present invention;

FIG. 7 is a sectional view showing the manufacturing process of the semiconductor device according to the embodiment of the present invention;

FIG. 8 is a sectional view showing the manufacturing process of the semiconductor device according to the embodiment of the present invention;

FIG. 9 is a sectional view showing the manufacturing process of the semiconductor device according to the embodiment of the present invention;

FIG. 10 is a sectional view showing the manufacturing process of the semiconductor device according to the embodiment of the present invention;

FIG. 11 is a view showing deposition temperature dependency on a concentration of impurities captured into an Al₂O₃ film formed according to the embodiment of the present invention;

FIG. 12 is a view showing a relation of a concentration of C captured into an Al₂O₃ film formed at 400° C. to a flow rate ratio of H₂ and TMA according to the embodiment of the present invention; and

FIGS. 13A and 13B are views showing situations of surface reactions of TMA when the TMA is supplied to the Al₂O₃ film according to the embodiment of the present invention.

### DETAILED DESCRIPTION OF THE INVENTION

Next, an embodiment of the present invention will be described with reference to the accompanying drawings.

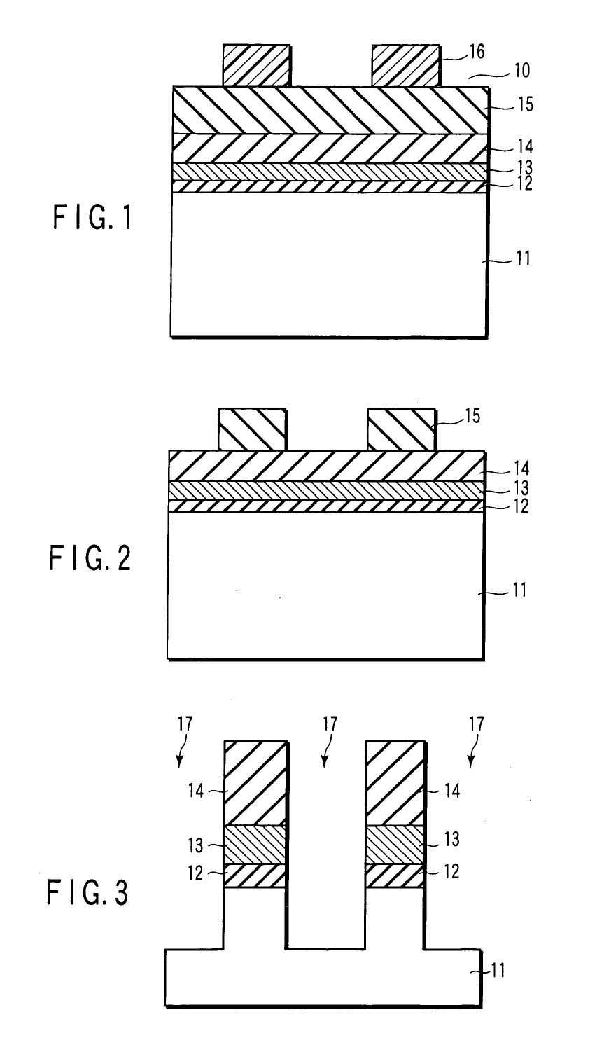

FIGS. 1 to 10 are sectional views showing a manufacturing process of a semiconductor device according to an embodiment of the present invention. Referring to FIGS. 1 to 10, a structure of the nonvolatile semiconductor device of the embodiment and its manufacturing method will be described.

First, as shown in FIG. 1, a first insulating film 12 is formed with a thickness of about 1 to 15 nm on a p-type silicon substrate 11 (or p-type well formed in an n-type silicon substrate). A first conductive layer 13 of polysilicon or the like is formed with a thickness of about 10 to 200 nm thereon to become a charge storage layer as a floating gate by a CVD method.

Subsequently, a silicon nitride film 14 is deposited with a thickness of about 50 to 200 nm by the CVD method, and a silicon oxide film 15 is formed with a thickness of about 50 to 400 nm. A photoresist is applied on the silicon oxide film 15, and patterned to form a resist mask 16.

Next, as shown in FIG. 2, the silicon oxide film 15 is selectively etched by using the resist mask 16 of FIG. 1. The resist mask 16 is removed after the etching. Then, as shown in FIG. 3, the silicon nitride film 14 is etched by using the silicon oxide film 15 as a mask, and the first conductive layer 13, the first insulating film 12, and the silicon substrate 11 are subsequently etched to form an element isolation trench 17. After the etching, a high-temperature oxidation process is carried out to remove damage to a section formed by the etching.

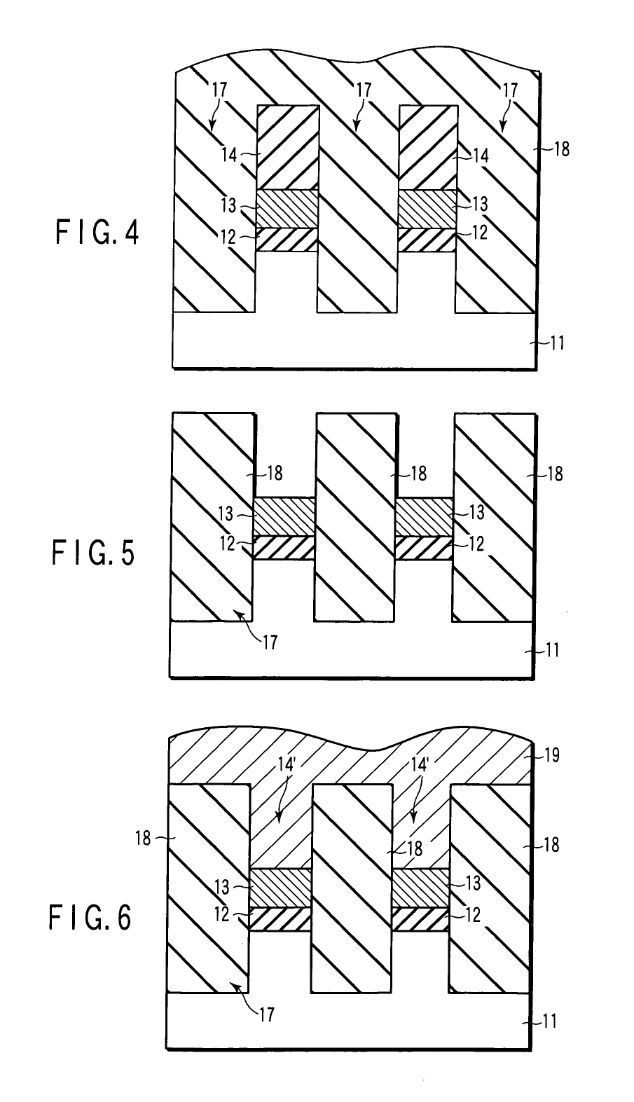

Next, as shown in FIG. 4, an insulating film 18 such as a silicon oxide film is deposited with a thickness of about 200 to 1500 nm to fill the element isolation trench 17, and a high-temperature heat treatment is carried out in a nitrogen or oxygen atmosphere to achieve a high density. Planarization is executed by a chemical mechanical polishing (CMP) method using the silicon nitride film 14 as a stopper. Subsequently, the silicon nitride film 14 is removed by using hot phosphorus which enables etching having a selection ratio with the silicon oxide film. Accordingly, a sectional structure as shown in FIG. 5 can be obtained.

According to the embodiment, when the element isolation trench 17 is formed, the stacked film of the silicon nitride and oxide films 14 and 15 is used as a mask. However, as long as film thickness and reactive ion etching conditions are properly set, even in the case of a single-layer silicon nitride film, a single-layer silicon oxide film, or other single-layer/multilayer films, a mask that can obtain a selection ratio with silicon can be used as a mask.

Next, as shown in FIG. 6, a second polysilicon conductive layer 19 that becomes a part of the first conductive layer 13 is deposited on a trench 14′ obtained after the removal of the silicon nitride film 14 and a buried insulating film 18 by using a method excellent in step coverage. The second conductive layer 19 is planarized by the CMP method using the buried insulating film 18 as a stopper.

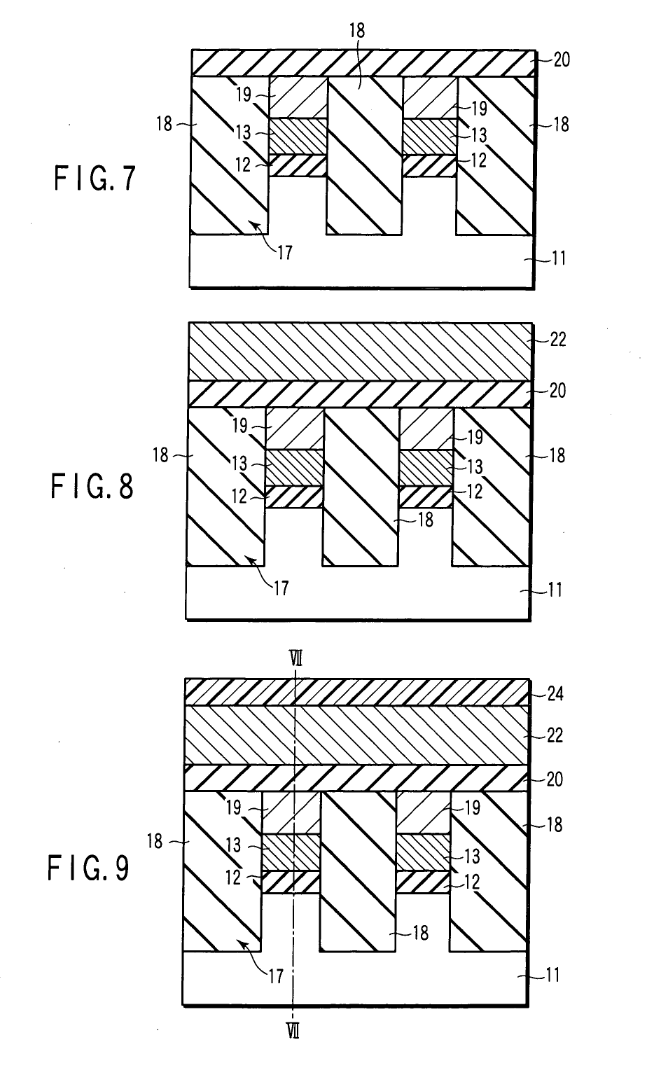

Next, as shown in FIG. 7, a second insulating film 20 having a dielectric constant higher than that of the silicon oxide film is formed on the insulating film 18 and the planarized second conductive layer 19. As the film having the high dielectric constant used for the second insulating film 20, a film having a relative dielectric constant higher than a relative dielectric constant of 3.8 to 4 of the silicon oxide film (SiO₂ film), especially than a relative dielectric constant of about 5 to 5.5 obtained for a conventional ONO film is preferable.

According to the embodiment, an Al₂O₃ film is used as a high dielectric constant film for the second insulating film 20. As its forming method, an ALD method that is a CVD method of adding H₂ (hydrogen) to a source gas is used. Details will be described below.

In a vacuum chamber whose pressure is held at 0.5 torr, trimethyl aluminum (TMA) which is a source gas of Al, H₂ and O₃ which is an oxidizing agent are alternately supplied to a wafer whose substrate temperature is heated to 380° C., whereby Al₂O₃ films are laminated in the form of a layer. This process is repeated by a desired number of times to deposit the film with a necessary thickness. Flow rates of source gases are set to 20 sccm for the TMA, 1000 sccm for H₂ at 5 slm, and the concentration of the O₃ is set to 250 g/m³.

The gas supply times are 1 second for TMA+H₂, and 3 seconds for the O₃. Between the supply of the TMA+H₂ and the O₃, N₂ for purging is supplied for 2 seconds at 5 slm. By executing this sequence at 120 cycles, an Al₂O₃ film having a thickness of 10 nm is obtained. A thickness of the second insulating film 20 is properly set in a range of 1 to 30 nm.

Subsequently, as shown in FIG. 8, a third conductive layer 22 that becomes a control gate, e.g., polysilicon, is formed with a thickness of 10 to 200 nm on the second insulating film 20. The third conductive layer 22 becomes a control gate in the nonvolatile semiconductor memory device.

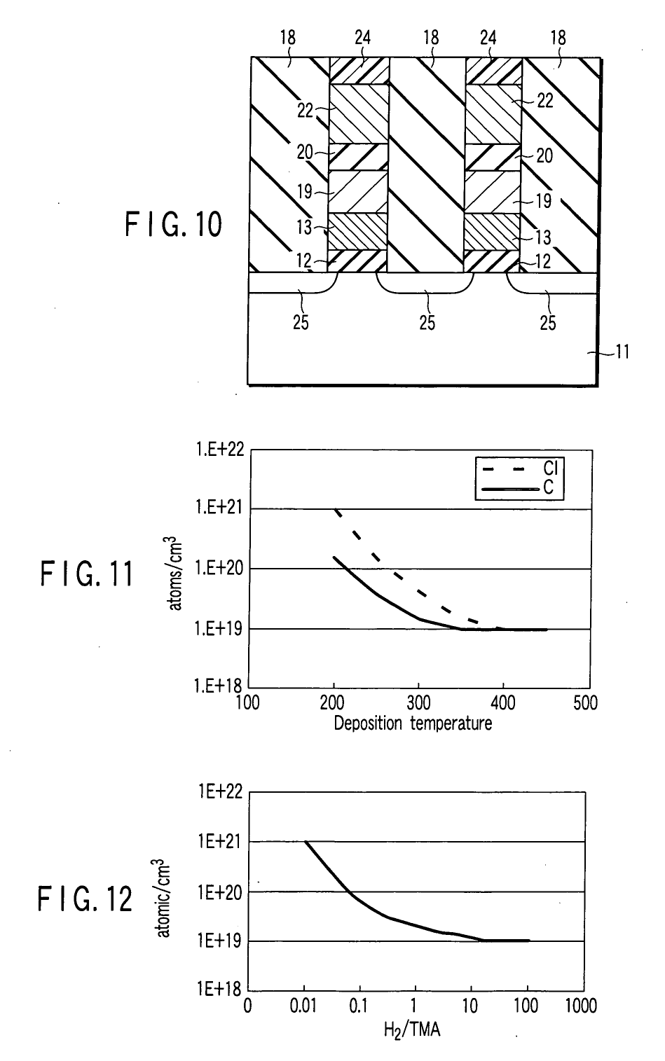

After the formation of the third conductive layer 22, annealing (post deposition annealing: PDA) is carried out in an atmosphere containing an oxidizing agent such as oxygen, ozone or water at a temperature of 500 to 1200° C. For example, furnace annealing is carried out for 10 minutes to 2 hours, or lamp annealing is carried out for 1 second to 30 minutes. Through this PDA, a high density of the second insulating film 20 is achieved to improve film quality. Then, as shown in FIG. 9, a resist 24 is applied on the third conductive layer 22, patterned to form a resist pattern, and etched to the first insulating film 12 by a normal method. Accordingly, a sectional structure as shown in FIG. 10 is formed.

FIG. 10 is a sectional view cut on the line VII-VII vertical to a paper surface of FIG. 9. As shown in FIG. 10, n-type impurities are introduced to a gate structure and a substrate surface exposed in self alignment, and then a heat treatment is carried out to form a source/drain region 25, thereby constituting each memory cell.

The embodiment has been described by way of case where the aluminum oxide (Al₂O₃) film is used for the second insulating film 20. However, as the high dielectric constant film of the second insulating film 20, a single-layer film of one selected from a magnesium oxide (MgO) film having a relative dielectric constant of about 10, an yttrium oxide (Y₂O₃) film having a relative dielectric constant of about 16, a hafnium oxide (HfO₂) film and a zirconium oxide (ZrO₂) film having relative dielectric constants of about 22, a tantalum oxide (Ta₂O₃) film having a relative dielectric constant of about 25, a bismuth oxide (Bi₂O₃) film, and a strontium oxide (SrO) film, or a composite layer film formed by staking a plurality thereof can be used. By adding H₂ to the source gas when the CVD method is used as a deposition method, it is possible to reduce impurities (incursion of elements other than the metal element of the source gas) in the oxide film. In the above description, the high dielectric constant film of the second insulating film 20 is formed indirectly on the silicon substrate 11, but the high dielectric constant film may be formed directly on the silicon substrate 11.

A sequence when an HfAlO film is formed as an example of a composite layer (compound oxide film) will be described. As methods of forming the HfAlO film, there are a method of stacking an HfO layer and an AlO layer, and a method of executing oxidation after formation of an HfAl mixture. In the case of stacking the HfO layer and the AlO layer, a mixed gas of an Hf source gas (e.g., tetrakis ethyl-methyl amino hafnium (TEMAH)) and H₂ is supplied to form an Hf adsorption layer, and then an oxidizing agent (e.g., O₃) is supplied to form an HfO layer. After the necessary number of HfO layers are formed, the necessary number of AlO layers are formed by the method described above, and then a next HfO layer is stacked to ultimately obtain a target film thickness and an Hf/Al composition ratio. As a method of forming an HfAl mixed layer, an Hf source gas, an Al source gas, and H₂ are simultaneously supplied to form an Hf and Al adsorption layer. Each gas flow rate is properly selected to adjust a composition ratio of Hf/Al to be adsorbed. Subsequently, an oxidizing agent is supplied to form an HfAl oxide. By properly repeating this process, it is possible to obtain an HfAlO film of a target thickness.

The embodiment has been described by way of the deposition method when the high dielectric constant film is used for the interpoly insulating film formed between the charge storage layer and the control electrode in the nonvolatile semiconductor memory device such as the flash memory. Additionally, it has been confirmed that as a deposition method when an oxide high dielectric constant film is used for a capacitor insulating film of a DRAM or for a gate insulating film, H₂ is added to a source gas to enable reduction of the amount of impurities, and good device characteristics can be obtained.

Regarding the method of simultaneously supplying TMA and H₂ to the silicon substrate, the following methods are available.

1) Method of separately disposing a TMA inlet, an H₂ inlet, and an O₃ inlet into the chamber in which the silicon substrate is contained, simultaneously supplying TMA and H₂ into the chamber, and stopping the supply of TMA and H₂ when O₃ is supplied.

2) Method of merging a TMA supply line and an H₂ supply line before supplying into the chamber to form a mixed gas of TMA and H₂, simultaneously supplying TMA and H₂ into the chamber, and supplying O₃ from a separately disposed O₃ inlet into the chamber.

3) Method of generating a mixed gas of TMA and H₂ during TMA bubbling by using H₂ or a mixed gas of H₂ and an inactive gas for a TAM carrier gas, and supplying the mixed gas into the chamber.

According to all the above methods, because of the presence of H₂ when TMA decomposition reaction occurs on the silicon substrate, it is possible to suppress capturing of C in the film.

The embodiment has been described by way of case where TMA is used for the Al source gas. Not only the organic gas but also an inorganic compound such as AlCl₃ are effectively used for the source gas. However, the effect of impurity reduction is higher when the organic metal compound is used as a source gas than that when the inorganic compound is used as a source gas.

FIG. 11 shows deposition temperature dependency of a concentration of impurities captured in an Al₂O₃ film formed by using AlCl₃ as an Al source gas according to the embodiment. In the case of AlCl₃, as reaction with H₂ occurs and deposition occurs while HCl is formed, a concentration of impurities is lower than that when no H₂ is added. However, vapor pressure of CH₄ generated by reaction of TMA+H₂ is higher than that of HCl generated by reaction of AlCl₃+H₂. Thus, the reduction effect of the concentration of impurities captured into the film is higher when the organic metal compound is used as the source gas than when the inorganic compound is used as the source gas.

The effect of the embodiment is improvement of electric characteristics realized by reducing the concentration of impurities in the Al₂O₃ film. In the nonvolatile memory device, especially in the case of a NAND, with higher integration, the gate electrode is thinner as a gate length is shorter. Accordingly, a distance becomes shorter between the high dielectric constant film such as an Al₂O₃ film and the gate insulating film. The impurities in the Al₂O₃ film are diffused through an interlayer film or the like to the gate by a post process heat treatment after the deposition, causing a fluctuation in transistor operation threshold. The embodiment has an effect of reducing this threshold fluctuation.

The embodiment has been described by way of case where the TMA flow rate is 20 sccm, and the H₂ flow rate is 100 sccm, i.e., the H₂/TMA is 50. However, it has been confirmed that an effect is obtained as long as the H₂/TMA flow rate ratio is equal to or more than 0.1, and there is a sufficient effect when it is 1 or more.

FIG. 12 shows a relation of a concentration of C captured into the Al₂O₃ film formed at 400° C. to the flow rate ratio of H₂ and TMA. With addition of H₂, reduction in the C concentration occurs, but TMA unreacted with H₂ is adsorbed thereon while the flow rate of H₂ is lower than that of TMA to be supplied, capturing of C into the Al₂O₃ film occurs. However, when the flow rate of H₂ exceeds the flow rate of TMA, TMA can sufficiently react with H₂, and thus the capturing of C can be sufficiently reduced.

According to the embodiment, by simultaneously supplying TMA and H₂, it is possible to reduce the amount of C in the Al₂O₃ film. Its mechanism will be described below.

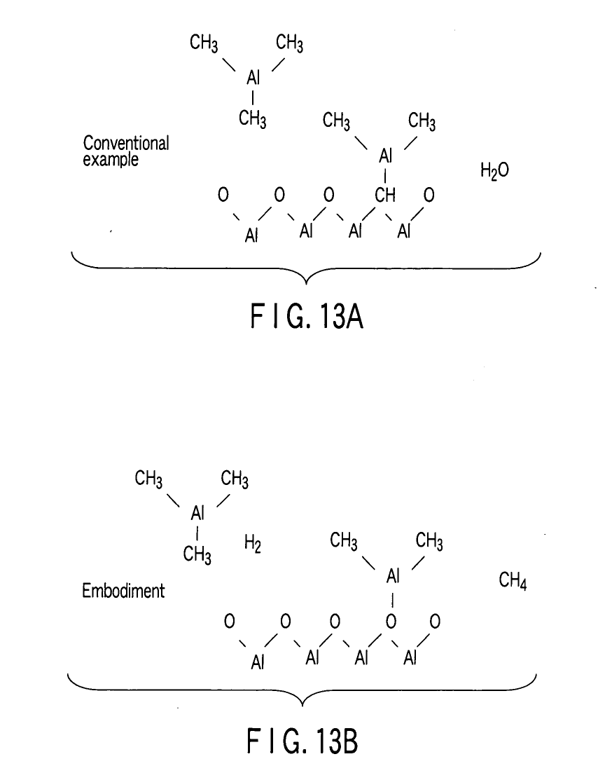

FIGS. 13A, 13B show situations of surface reactions of TMA when it is supplied to the Al₂O₃ film. When TMA alone is supplied as in the case of a conventional example shown in FIG. 13A, TMA reacts with O of the surface to cause a reaction of generating and adsorbing H₂O. In this case, as the adsorption occurs without disconnection of Al—C, C is left in the film even if O₃ oxidation is carried out thereafter. On the other hand, when TMA adsorption is carried out in an H₂ atmosphere as in the case of the embodiment shown in FIG. 13B, a CH₃ radical in TMA can react with H₂ causing a TMA surface adsorption reaction while Al—O connection is created. Accordingly, capturing of C into the Al₂O₃ film during O₃ oxidation executed thereafter is prevented.

Thus, the impurities caused by the source gas (incursion of elements other than the metal element constituting the source gas) can be reduced, whereby leakage current can be reduced, and a dielectric constant can be increased. Hence, it is possible to provide a semiconductor device having good characteristics.

As apparent from the foregoing, according to the embodiment, regarding the semiconductor device, especially the device equipped with the capacitor and the transistor using the high dielectric constant insulating film, it is possible to provide a semiconductor device having good characteristics by reducing the leakage current of the high dielectric constant insulating film and increasing the dielectric constant.

Specifically, by using the oxide for the high dielectric constant insulating film, using the DVD method as its production method, and adding H₂ to the source gas of the CVD method, the amount of C in the oxide insulating film can be reduced. Hence, it is possible to provide a high dielectric insulting film of good electrical characteristics.

According to the embodiment, it is possible to provide a method of manufacturing a semiconductor device, capable of reducing the leakage current of an insulating film and increasing the dielectric constant.

Additional advantages and modifications will is readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device, comprising:
simultaneously supplying a source gas of an oxide insulating film and H₂ to a semiconductor substrate when the oxide insulating film is formed on the semiconductor substrate by a CVD method.

2. The method according to claim 1, wherein the CVD method is an ALD method of alternately supplying a source gas for a metal element of the oxide insulating film and an oxidizing agent, and H₂ is added to the source gas of the metal element.

3. The method according to claim 1, wherein the oxide insulating film contains at least one selected from the group consisting of Al, Hf, Ta, Zr, Y, Bi, and Sr.

4. The method according to claim 1, wherein the oxide insulating film includes Al₂O₃.

5. The method according to claim 1, wherein the oxide insulating film is a composite layer film.

6. The method according to claim 5, wherein the composite layer film includes HfAlO.

7. The method according to claim 1, wherein the source gas is TMA.

8. The method according to claim 7, wherein the H₂/TMA flow rate ratio is equal to or more than 0.1.

9. The method according to claim 1, wherein the source gas contains an organic metal.

10. The method according to claim 1, wherein the source gas and H₂ form a mixed gas.

11. The method according to claim 1, wherein the source gas contains an inorganic compound.

12. The method according to claim 11, wherein the inorganic compound is AlCl₃.

13. The method according to claim 1, wherein said supplying a source gas of an oxide insulating film and H₂ further comprises:
separately disposing a source gas inlet, an H₂ inlet, and an O₃ inlet into a chamber in which the semiconductor substrate is contained;
simultaneously supplying the source gas and H₂ into the chamber; and
stopping the supply of the source gas and H₂ when O₃ is supplied.

14. The method according to claim 1, wherein said supplying a source gas of an oxide insulating film and H₂ further comprises:
merging a source gas supply line and an H₂ supply line before supplying into a chamber in which the semiconductor substrate is contained to form a mixed gas of the source gas and H₂;
simultaneously supplying the source gas and H₂ into the chamber; and
supplying O₃ from a separately disposed O₃ inlet into the chamber.

15. The method according to claim 1, wherein said supplying a source gas of an oxide insulating film and H₂ further comprises:
generating a mixed gas of the source gas and H₂ during source gas bubbling by using H₂ or a mixed gas of H₂ and an inactive gas for a source gas carrier gas; and
supplying the mixed gas into a chamber in which the semiconductor-substrate is contained.
